(19) United States
(12) Patent Application Publication
(10) Pub. No.: US 2017/0301681 A1
(43) Pub. Date: Oct. 19, 2017

(54) CONFIGURABLE ROM

(71) Applicant: STMicroelectronics SA, Montrouge (FR)

(72) Inventors: Stephane Denorme, Crolles (FR); Philippe Candelier, Saint Mury (FR)

(73) Assignee: STMicroelectronics SA, Montrouge (FR)

(21) Appl. No.: 15/377,861

(22) Filed: Dec. 13, 2016

(30) Foreign Application Priority Data
Apr. 14, 2016 (FR) 1653287

(51) Int. Cl. H01L 27/112; H01L 23/00; H01L 23/525; H01L 27/02; G11C 17/16

(52) U.S. Cl. CPC H01L 27/11206; H01L 27/0203; G11C 17/16; H01L 23/5252; H01L 23/57

(57) ABSTRACT

A configurable read only memory (ROM) including a number of memory cells. The memory cells include first-type memory cells that are electrically-programmable antifuses and second-type memory cells that are antifuses programmed by masking.

### PRIORITY CLAIM

This application claims the priority benefit of French Application for U.S. Pat. No. 1,653,287, filed on Apr. 14, 2016, the disclosure of which is hereby incorporated by reference in its entirety.

### TECHNICAL FIELD

The present disclosure relates to a configurable antifuse read-only memory (ROM). It particularly relates to one-time programmable (OTP) memories.

### BACKGROUND

FIG. 1 is an electric diagram illustrating an example of antifuse and of its access transistor. Such an antifuse comprises a capacitor 1 and is series-connected with access transistor 3. Source 5 of transistor 3 is connected to a voltage source V_{S}, gate 7 of transistor 3 is connected to a voltage source V_{G}, and drain 9 of transistor 3 is connected to a first terminal of capacitor 1. The free terminal or plate of capacitor 1 is connected to a voltage source V_{HT}. In the initial state, the antifuse is said to be unprogrammed. Its impedance is, for example, in the order of one GΩ. When a high voltage is applied to the capacitor, the latter breaks down and enters a low-impedance state, for example, in the order of 10 kΩ. The antifuse is said to be programmed. For capacitor 1 to break down, an addressing voltage V_{G} is applied to the transistor gate and a strong voltage difference V_{HT}-V_{S} is applied between the free terminal of capacitor 1 and source 5 of transistor 3. Antifuses of this type are used as memory cells in memory arrays. To program such a memory array, the terminals of application of voltages V_{S}, V_{G}, V_{HT} are distributed on rows and columns of the memory array.

FIG. 2 is a diagram illustrating an embodiment of the antifuse and of its access transistor 3 of FIG. 1. The drawing shows capacitor 1 in series with access transistor 3 having a source 5, a gate 7, and a drain 9 as well as the terminals of application of voltages V_{S}, V_{G}, V_{HT}. Capacitor 1 and transistor 3 are formed on a same semiconductor substrate 11. Source 5 of transistor 3 is formed by a heavily-doped N portion of substrate 11 (N+) supporting an electric contact. The electric contact is connected by a via 13 to a first electrode 15 formed in a first metallization level, forming the terminal of application of voltage V_{S}. Gate 7 of transistor 3 is formed on a layer 17 of insulating gate material resting on a portion of the substrate which is little or not P-type doped (P−). An electric gate contact is connected by a via 19 to a second gate electrode 21 formed in the first metallization level, forming the terminal of application of voltage V_{G}. Drain 9 of transistor 3 is formed by a heavily-doped N-type substrate portion (N+). This portion also forms the first plate of capacitor 1. Indeed, a layer 23 of insulating material having a substantially equal thickness and the same structure as layer 17 rests on this portion. Layer 23 supports second plate 25 of the capacitor. An electric contact which is connected by a via 27 to a third electrode 29 formed in the first metallization level, forming the terminal of application of voltage V_{HT}, is located on plate 25.

To have access to data stored in a memory using antifuses of this type, a pirate may, by means of an electronic scan microscope, scan the structure with electrons and apply bias voltages. The programmed memory cells having a current flowing therethrough will then appear as light spots. Such an attack may be carried out from the upper surface, after having delaminated the metallization levels formed on the components in order to reach electrodes 15, 21, 29 of the first metallization level. The attack may also be performed from the lower surface, preferably after having thinned the substrate.

### SUMMARY

An embodiment aims at forming a configurable ROM which avoids at least some of the disadvantages of existing devices.

An embodiment aims at forming a configurable ROM which is less vulnerable to pirate attacks.

Thus, an embodiment provides a configurable ROM comprising electrically-programmable antifuses and antifuses programmed by masking.

According to an embodiment, an electrically-programmable antifuse comprises a capacitor, the capacitor being series-connected with an access transistor, the capacitor comprising a plate resting on a layer of insulating material, electric contacts being formed on the transistor gate, on the main region of the transistor opposite the capacitor, and on the capacitor plate.

According to an embodiment, an antifuse programmed by masking comprises the components of an electrically-programmable antifuse and further comprises an electric contact on the substrate between the transistor and the capacitor.

According to an embodiment, each of said electric contacts is connected by a via to an electrode formed in a first metallization level.

According to an embodiment, the electrode of the capacitor of an electrically-programmable antifuse has a shape and dimensions identical to those of the electrode of the capacitor of an antifuse programmed by masking.

According to an embodiment, the layer of insulating material has the same thickness and is made of the same material(s) as the gate insulator layer of the access transistor.

According to an embodiment, the layer of insulating material and the gate insulating layer have a thickness in the range from 1 to 10 nm.

### BRIEF DESCRIPTION OF THE DRAWINGS

The foregoing and other features and advantages will be discussed in detail in the following non-limiting description of specific embodiments in connection with the accompanying drawings, wherein:

FIG. 1 shows the electric diagram of an electrically programmable antifuse and of its access transistor;

FIG. 2 is a cross-section view illustrating an embodiment of an electrically-programmable antifuse and of its access transistor;

FIG. 3 is a cross-section view illustrating an embodiment of an antifuse programmed by masking and of its access transistor;

FIG. 4 is a top view of an embodiment of an antifuse programmed by masking and of its access transistor;

FIG. 5 is a top view of an embodiment of an electrically-programmable antifuse and of its access transistor; and

FIG. 6 shows an embodiment of a configurable ROM array.

### DETAILED DESCRIPTION OF THE DRAWINGS

The same elements have been designated with the same reference numerals in the different drawings and, further, the various drawings are not to scale. For clarity, only those steps and elements which are useful to the understanding of the described embodiments have been shown and are detailed.

In the following description, when reference is made to terms qualifying the relative position, such as term “top”, “lower”, and “upper”, reference is made to the orientation of the concerned elements in the drawings. Unless otherwise specified, expression “in the order of” means to within 10%, preferably to within 5%.

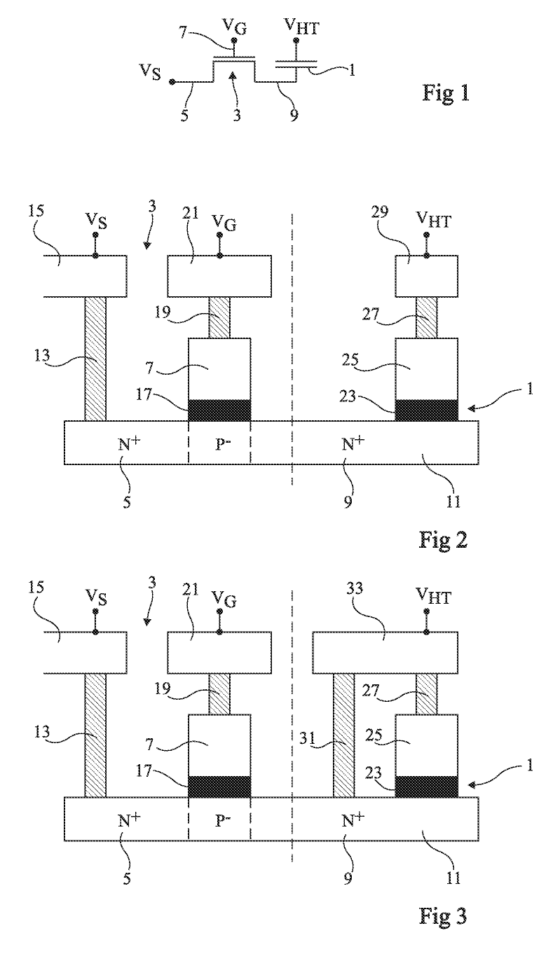

FIG. 3 is a cross-section view of an embodiment of an antifuse programmed by masking and of its access transistor. In this drawing, the same elements as in FIGS. 1 and 2 are designated with the same reference numerals. The antifuse of FIG. 3 has the same general configuration as the antifuse of FIG. 2 and further comprises an electric contact on drain 9 of the transistor in the vicinity of capacitor 1. The contact is connected by a via 31 to an electrode 33 forming the terminal of application of voltage V_{HT}. Layer 23 has a thickness in the range from 1 nm to 10 nm and may be formed of a simple layer of insulating material or of a stack of layers of insulating material. As an example, the insulating material may be silicon dioxide or hafnium dioxide. Electrode 33 has a sufficient extension to cover vias 27 and 31. Via 31 thus short-circuits capacitor 1. Via 31 is defined by the mask especially defining via 13 connecting source 5 of transistor 3 to electrode 15 forming the terminal of access to voltage VS. The antifuse is thus programmed by manufacturing.

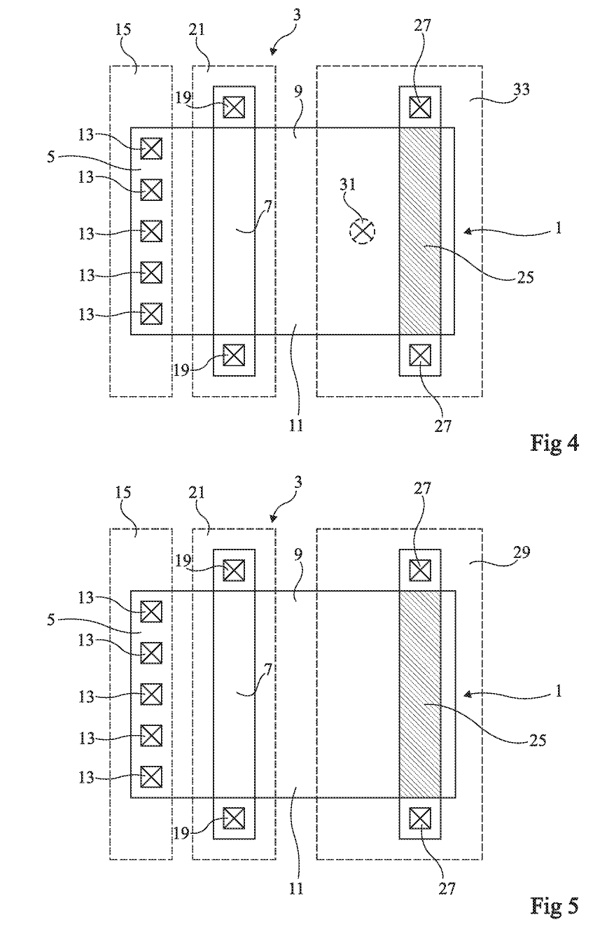

FIG. 4 is a top view of an embodiment of an antifuse programmed by masking of the type of that in FIG. 3. Transistor 3 and capacitor 1 are formed on a semiconductor substrate 11 having a rectangular contour. Plate 25 of capacitor 1 rests on layer 23 of insulating material (not shown in FIG. 4), which itself rests on drain 9 of transistor 3. In the shown example, plate 25 extends all the way to contact areas from which two symmetrical vias 27 are formed. Electrodes 15, 21, and 33 are delimited as shown in dotted lines. Electrode 33, forming the terminal of application of voltage V_{HT}, covers, in particular, via 31 and vias 27.

FIG. 5 is a top view of an embodiment of an electrically-programmable antifuse and of its access transistor of FIG. 2. In this drawing, the same elements as in FIG. 4 are designated with the same reference numerals. Electrode 29 forming the terminal of application of voltage V_{HT} is formed to have the same shape and the same extension as electrode 33 of the antifuse programmed by masking of FIG. 4. Thereby, in top view, the electrically-programmable antifuse and the antifuse programmed by masking are identical.

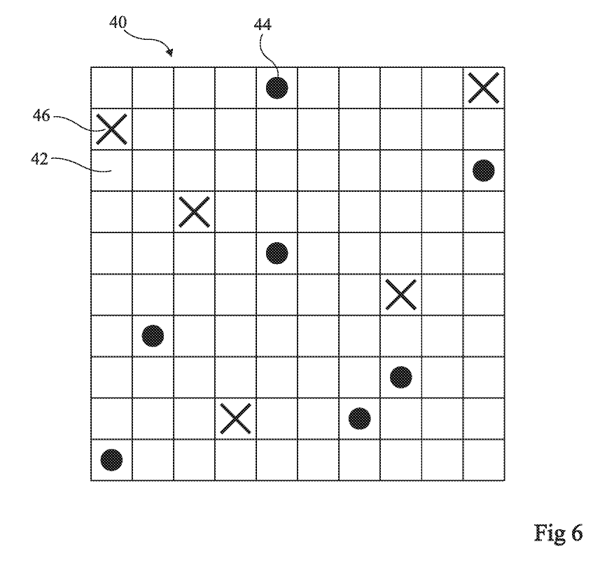

FIG. 6 is a simplified top view of an array 40 of memory cells of a configurable ROM.

Such a configurable ROM comprises electrically-programmable antifuses and antifuses programmed by masking.

The white memory cells 42 are electrically programmable antifuses in the unprogrammed state. The memory cells 44 marked with a black dot are electrically-programmable antifuses in the programmed state. The memory cells 46 marked with a cross are antifuses programmed by masking. The impedance of an antifuse programmed by masking is, for example in the order of 10Ω and is smaller than the impedance of an electrically-programmable antifuse in the programmed state, which is, for example, in the order of 10 kΩ.

An optical observation of the two types of antifuses does not enable to tell them from each other since they have an identical aspect.

With an electronic scan microscope observation as described in the discussion above, it may be desired to view the state of the different types of antifuses. Antifuses programmed by masking have a lower impedance than electrically-programmable antifuses and conduct a largest electron flow. A pirate will then see sharp light spots for antifuses programmed by masking. However, electrically-programmable antifuses in the programmed state cannot be distinguished from unprogrammed antifuses. A pirate can thus believe that the programmed cells marked with a black dot in FIG. 6 are unprogrammed and will not have access to all the data stored in the memory.

Specific embodiments have been described. Various alterations, modifications, and improvements will readily occur to those skilled in the art. In particular:
the doped semiconductor substrate may correspond to wells formed in a solid semiconductor substrate, or to a silicon-on-insulator structure (SOI);
the mentioned biasing can all be inverted;
the impedance values have only been given as an example;
the described capacitor may be replaced with any other type of antifuse having a first high-resistivity state and a second low-resistivity state;
a plurality of series-connected access transistors may be used, for example, three, to withstand the high voltages implied in programming operations.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A configurable read only memory (ROM), comprising:
electrically-programmable antifuses; and
antifuses programmed by masking.

2. The configurable ROM of claim 1, wherein at least one of said electrically-programmable antifuses comprises a capacitor, the capacitor being series-connected with an access transistor, the capacitor comprising a plate resting on a layer of insulating material, electric contacts being formed on a gate of the access transistor, on the main region of the transistor opposite the capacitor, and on the capacitor plate.

3. The configurable ROM of claim 2, wherein at least one of said antifuses programmed by masking comprises components of said electrically-programmable antifuse and further comprises an electric contact on the substrate between the transistor and the capacitor.

4. The configurable ROM of claim 2, wherein each of said electric contacts is connected by a via to an electrode formed in a first metallization level.

5. The configurable ROM of claim 4, wherein the electrode of the capacitor for each electrically-programmable antifuse has a shape and dimensions identical to those of the electrode of the capacitor of each antifuse programmed by masking.

6. The configurable ROM of claim 2, wherein the layer of insulating material has the same thickness and is made of same material(s) as a gate insulator layer of the access transistor.

7. The configurable ROM of claim 6, wherein the layer of insulating material and the gate insulator layer have a thickness in the range from 1 to 10 nm.

8. A configurable read only memory (ROM), comprising a plurality of memory cells, said plurality of memory cells wherein each memory cell includes a capacitor coupled in series with an access transistor, the plurality of memory cells including:
first-type memory cells electrically-programmable by selectively breaking down a dielectric of the capacitor; and
second-type memory cells including a circuit element that bypasses the capacitor and directly connects a terminal of the access transistor to a voltage source node.

9. The configurable ROM of claim 8, further including a first metallization level including a metal line configured as said voltage source node, wherein each second-type memory cell includes an electrical contact positioned underneath said metal line that directly connects the terminal of the access transistor to the metal line.

10. The configurable ROM of claim 8, wherein an electrode of the capacitor for each memory cell of both the first-type and second-type has an identical shape and identical dimension.

11. The configurable ROM of claim 8, wherein, for each memory cell of both the first-type and second-type, the dielectric of the capacitor has a same thickness and is made of a same material as a gate insulator layer of the access transistor.

12. The configurable ROM of claim 11, wherein said same thickness is in the range from 1 to 10 nm.

13. A method for protecting a configurable read only memory (ROM), said ROM comprising a plurality of memory cells wherein each memory cell includes a capacitor coupled in series with an access transistor, from discovery of programmed data state, comprising:
programming first-type memory cells of said plurality of memory cells by selectively breaking down a dielectric of the capacitor; and
fixed programming of second-type memory cells of said plurality of memory cells by directly connecting a terminal of the access transistor to a voltage source node so as to bypass the capacitor.

14. The method of claim 13, wherein directly connecting further includes hiding an electrical contact that directly connects the terminal of the access transistor to the voltage source node underneath a metal line of a first metallization level that is configured as said voltage source node.
